(19) United States
(12) Patent Application Publication
(10) Pub. No.: US 2019/0379808 A1
(43) Pub. Date: Dec. 12, 2019

(54) CIRCUIT BOARD, CAMERA MODULE, AND METHOD FOR LABELING THE CIRCUIT BOARD

(71) Applicants: TRIPLE WIN TECHNOLOGY(SHENZHEN) CO.LTD., Shenzhen (CN); HON HAI PRECISION INDUSTRY CO., LTD., New Taipei (TW)

(72) Inventors: SHIN-WEN CHEN, Tu-Cheng (TW); SHENG-JIE DING, Shenzhen (CN); JING-WEI LI, Shenzhen (CN); JIAN-CHAO SONG, Shenzhen (CN)

(21) Appl. No.: 16/167,517

(22) Filed: Oct. 22, 2018

(30) Foreign Application Priority Data
Jun. 11, 2018 (CN) 201810599395.X

(51) Int. Cl. H04N 5/225; H05K 1/02; H05K 1/18

(52) U.S. Cl. CPC H04N 5/2254; H05K 1/0266; H04N 5/2257; H05K 2201/10121; H05K 2201/09918; H05K 2201/10151; H05K 1/189

(57) ABSTRACT

A circuit board includes an assembly and a labeling area. The assembly area is for installation of the elements. The labeling area is for marking of the circuit board. A paint layer is coated on a surface of the labeling area. A two-dimensional code is printed on the paint layer. A camera module having the circuit board and a method for labeling the circuit board are also provided.

### FIELD

The subject matter relates to circuit board, and more particularly, to a circuit board, a camera module having the circuit board, and a method for labeling the circuit board.

### BACKGROUND

Camera modules generally comprise carrier substrates, image sensors, lens holders, and lens barrels. The image sensor and the lens holder are fixed on the substrate. The lens barrel is housed in the lens holder. During manufacturing, in order to track the camera module, a barcode or a serial number is attached to the camera module. Or, a steel sheet with laser printed two-dimensional code is printed on a printed circuit board of the camera module. However, the bar code or the serial number may be easily damaged and fall off, causing it to be inconvenient for long-term preservation. Furthermore, laser printing of the two-dimensional codes on steel sheets has relatively high prices and increases the cost of camera modules.

Accordingly, there is room for improvement within the art.

### BRIEF DESCRIPTION OF THE DRAWINGS

Implementations of the present technology will now be described, by way of example only, with reference to the attached figures, wherein:

FIG. 1 is a diagram of a first embodiment of a camera module.

FIG. 2 is an exploded diagram of the camera module of FIG. 1.

FIG. 3 is a flow chart of a method for labeling a circuit board of the camera module in FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details.

In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

One definition that applies throughout this disclosure will now be presented.

The term “substantially” is defined to be essentially conforming to the particular dimension, shape, or other feature that the term modifies, such that the component need not be exact. For example, “substantially rectangular” means that the object resembles a rectangle, but can have one or more deviations from a true rectangle.

The term “comprising,” when utilized, means “including, but not necessarily limited to”; it specifically indicates open-ended inclusion or membership in the so-described combination, assembly, series, and the like.

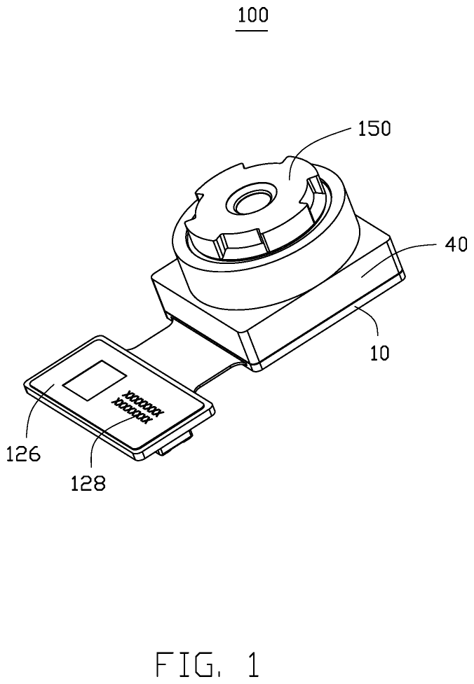

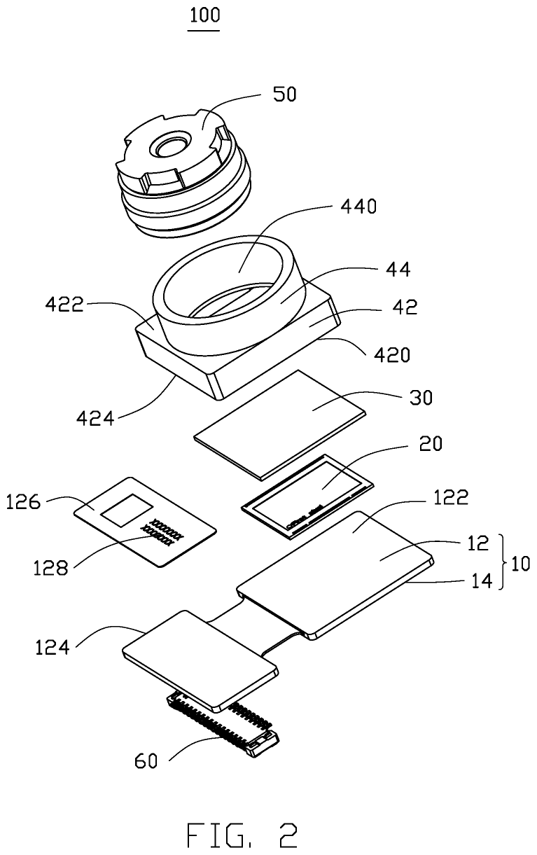

FIGS. 1 and 2 show an embodiment of a camera module 100. The camera module 100 includes a circuit board 10, an image sensor 20, a protective plate 30, a lens holder 40, and a lens barrel 50.

The circuit board 10 includes a first surface 12 and a second surface 14. The first surface 12 and the second surface 14 are located on opposite surfaces of the circuit board 10 and, typically, the first surface 12 will be an upper surface and the second surface 14 will be a lower surface. In an embodiment, the first surface 12 is parallel to the second surface 14. The first surface 12 includes an assembly area 122 and a labeling area 124. The assembly area 122 connects to the labeling area 124. In an embodiment, the assembly area 122 and the labeling area 124 are connected by a flexible board. The labeling area 124 is coated with a paint layer 126. The color of the paint layer 126 can be varied as needed. In an embodiment, the paint layer 126 is white. A two-dimensional code 128 is printed on the paint layer 126. In an embodiment, the two-dimensional code 128 is formed by laser printing.

The image sensor 20 is fixed on the assembly area 122, and is electrically connected to the circuit board 10.

The protective plate 30 is positioned on the assembly area 122, and covers the image sensor 20. The protective plate 30 is configured to protect the image sensor 20 from being contaminated by dust and other contaminants. The protective plate 30 may be a glass substrate or a transparent plastic plate. In the embodiment, the protective plate 30 is a glass substrate.

The lens holder 40 is fixed on the assembly area 122. The lens holder 40 is made of plastic. The image sensor 20 and the protective plate 30 are both accommodated in the lens holder 40. The lens holder 40 includes a base 42 and a receiving portion 44. The receiving portion 44 is disposed on the base 42.

The base 42 is substantially rectangular. The base 42 includes a top surface 422 and a bottom surface 424. The top surface 422 and the bottom surface 424 are located at opposite ends of the base 42. In the embodiment, the top surface 422 is parallel to the bottom surface 424. A first opening 420 is defined in the base 42. The first opening 420 penetrates the top surface 422 and the bottom surface 424. The first opening 420 is rectangular. The first opening 420 is configured for receiving the image sensor 20 and the protective plate 30.

The receiving portion 44 is substantially cylindrical. A second opening 440 is defined in the receiving portion 44. The second opening 440 is configured for receiving the lens barrel 50. The second opening 440 goes through the receiving portion 44. The second opening 440 is cylindrical. The second opening 440 connects to the first opening 420.

The lens barrel 50 is made of a metal. The lens barrel 50 is accommodated in the second opening 440. The diameter of the lens barrel 50 matches the diameter of the second opening 440.

The camera module 100 also comprises a connector 60. The connector 60 is configured to connect the camera module 100 to other electronic devices (not shown). The connector 60 is fixed on the second surface 14, and is opposite to the paint layer 126. In other embodiments, the connector 60 can also be formed on the labeling area 124. The paint layer 126 and the two-dimensional code 128 are formed on the second surface 14.

During installation, the image sensor 20 and the protective plate 30 are fixed to the assembly area 122. The lens holder 40 is fixed on the circuit board 10. The image sensor 20 and the protective plate 30 are accommodated in the first opening 420. The lens barrel 50 is positioned in the second opening 440. The position of the lens barrel 50 is adjusted to cause the central axis of the lens barrel 50 to be aligned with the center of the image area of the image sensor 20.

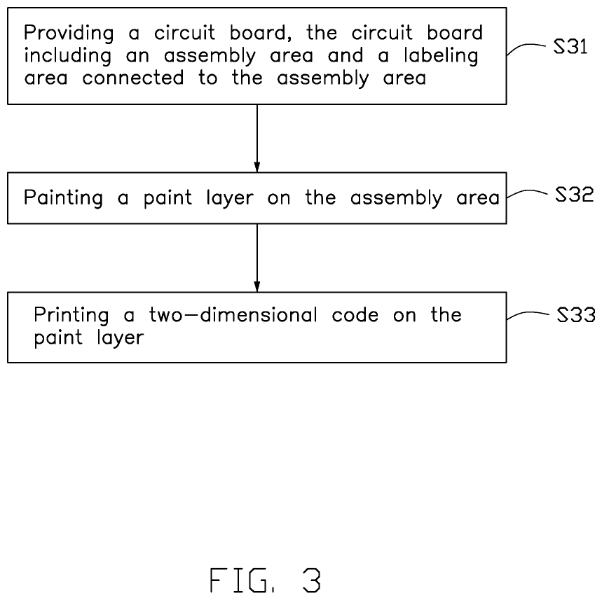

FIG. 3 shows an embodiment of a method for marking the circuit board 10. The method is provided by way of example, as there are a variety of ways to carry out the method. Each block shown in the figure represents one or more processes, methods, or subroutines, carried out in the example method. Furthermore, the illustrated order of blocks is illustrative only and the order of the blocks can change. Additional blocks can be added or fewer blocks may be utilized or the order of the blocks may be changed, without departing from this disclosure. The method can begin at block 31.

At block 31, a circuit board 10 is provided, the circuit board 10 includes an assembly area 122 and a labeling area 124 connected to the assembly area 122.

The circuit board 10 includes a first surface 12 and a second surface 14 opposite to each other. The first surface 12 includes the assembly area 122 and the labeling area 124.

At block 32, a paint layer 126 is painted on the assembly area 122.

The paint layer 126 is formed on the labeling area 124.

At block 33, a two-dimensional code 128 is printed on the paint layer 126.

The two-dimensional code 128 is printed on the paint layer 126.

In an embodiment, the paint layer 126 includes white paint. The two-dimensional code 128 is formed by laser.

With the above configuration, the paint layer 126 is coated on the circuit board 10, and the two-dimensional code 128 is printed on the paint layer 126. The paint layer 126 and the two-dimensional code 128 are not easily damaged and fall off, which facilitates for long-term preservation. The method for marking the circuit board 10 is simple which reduces the cost.

The embodiments shown and described above are only examples. Many details are often found in the art. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A circuit board comprising:
an assembly area; and
a labeling area connected to the assembly area;
wherein a paint layer is coated on a surface of the labeling area, a two-dimensional code is printed on the paint layer.

2. The circuit board of claim 1, wherein the two-dimensional code is formed by laser.

3. The circuit board of claim 1, wherein the paint layer is white paint.

4. A camera module comprising:
a circuit board comprising:
an assembly area for installation of the elements;
a labeling area for marking of the circuit board;
wherein a paint layer is coated on a surface of the labeling area, a two-dimensional code is printed on the paint layer.

5. The camera module of claim 4, wherein the two-dimensional code is printed on the paint layer by laser.

6. The camera module of claim 5, wherein the paint layer is white paint.

7. The camera module of claim 5, further comprising a connector, wherein the connector is fixed on the labeling area and is opposite to the paint layer.

8. A method for labeling circuit board, comprising:
providing a circuit board, the circuit board comprising an assembly area and a labeling area connected to the assembly area.
painting a paint layer on the assembly area; and
printing a two-dimensional code on the paint layer.

9. The method of claim 8, wherein the two-dimensional code is printed on the paint layer by laser.

10. The method of claim 8, wherein the paint layer is white paint.
